(19) United States
(12) Patent Application Publication
(10) Pub. No.: US 2023/0280257 A1
(43) Pub. Date: Sep. 7, 2023

(54) APPARATUS FOR STUDYING GLOBAL EFFECTS OF LOCALLY NONCHAOTIC ELEMENTS

(71) Applicant: The Regents of the University of California, Oakland, CA (US)

(72) Inventors: Yu Qiao, San Diego, CA (US); Meng Wang, Pleasanton, CA (US); Rui Kou, Shenzhen (CN); Zhaoru Shang, La Jolla, CA (US)

(21) Appl. No.: 18/114,948

(22) Filed: Feb. 27, 2023

Related U.S. Application Data
(63) Continuation-in-part of application No. PCT/US2021/048231, filed on Aug. 30, 2021.
(60) Provisional application No. 63/072,786, filed on Aug. 31, 2020.

(51) Int. Cl. G01N 15/06; G06F 30/25

(52) U.S. Cl. CPC G01N 15/06; G06F 30/25

(57) ABSTRACT

A system is described. The system includes a first region and a second region. The first region is configured to retain particles and has a first characteristic dimension. The second region is communicatively coupled with the first region such that the particles can travel between the first region and the second region. The second region has a second characteristic dimension of not larger than twice a characteristic length for the particles. The second region has a barrier that offers resistance to or interruption in particle movement.

### CROSS REFERENCE TO OTHER APPLICATIONS

This application is a continuation in part of PCT Application No. PCT/US21/48231 entitled SPONTANEOUSLY NONEQUILIBRIUM SYSTEM filed Aug. 30, 2021, which claims priority to U.S. Provisional Application No. 63/072,786 entitled SPONTANEOUSLY NONEQUILIBRIUM SYSTEM filed Aug. 31, 2020, both of which are incorporated herein by reference for all purposes.

### BACKGROUND OF THE INVENTION

Ergodicity and chaoticity are fundamental concepts in science and technology. Ergodic theory is the theory of the long-term statistical behavior of dynamical systems that arose out of an attempt to understand the long-term statistical behavior of dynamical systems such as the motions of a group of billiard balls or the motions of the earth's atmosphere. It is well known that an ergodic and chaotic system can reach thermodynamic equilibrium. For example, when the pressures of ideal gas in two connected containers are the same, entropy is maximized. In such ergodic and/or chaotic systems, the characteristic dimensions are generally much larger than characteristic lengths for the particles being studied. Such ergodic and/or chaotic system may be readily studied using known techniques.

In some configurations of the container, particles in the system may be nonchaotic and/or nonergodic. Such systems may have interesting properties. One example is the Knudsen gas. A Knudsen gas is contained in a small container, with the characteristic container size smaller than the particle mean free path. Although the behavior of a Knudsen gas and other nonchaotic systems have been studied (e.g. for the Knudsen paradox and the Knudsen effect), direct investigation of the properties of Knudsen gas or other nonchaotic systems can be difficult. Accordingly, what is needed is a technique that may facilitate study of such systems.

### BRIEF DESCRIPTION OF THE DRAWINGS

Various embodiments of the invention are disclosed in the following detailed description and the accompanying drawings.

FIG. 1 is a block diagram of an embodiment of a system usable in studying nonchaotic behavior.

FIG. 2 is a block diagram of an embodiment of a system usable in studying nonchaotic behavior.

FIG. 3 is a block diagram of an embodiment of a system usable in studying nonchaotic behavior.

FIGS. 4A-4C are diagrams depicting an embodiment of a system usable in studying nonchaotic behavior.

FIG. 5 is a diagram of an embodiment of a system usable in studying nonchaotic behavior.

FIGS. 6A-6B are diagrams depicting an embodiment of a system usable in studying nonchaotic behavior.

FIGS. 7A-7B are diagrams depicting an embodiment of a system usable in studying nonchaotic behavior.

FIG. 8 is a diagram of an embodiment of a system usable in studying nonchaotic behavior.

FIG. 9 is a flow-chart depicting an embodiment of a method usable in studying nonchaotic behavior.

FIGS. 10-11 are diagrams depicting an embodiment of a system usable in studying nonchaotic behavior.

FIG. 12 indicates typical experimental results.

FIGS. 13A-13B depicts an asymmetric membrane usable in investigating the behavior of particles in nonchaotic systems.

FIG. 14 depicts an embodiment of an experimental setup usable with the membrane.

FIG. 15 depicts an embodiment of a system usable in investigating the behavior or particles in nonchaotic systems.

FIGS. 16A-16C depict an embodiment of a system usable in investigating the behavior or particles in nonchaotic systems during formation.

### DETAILED DESCRIPTION

The invention can be implemented in numerous ways, including as a process; an apparatus; a system; a composition of matter; a material; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a material described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A system including a first region and a second region is described. The first region is configured to retain particles and has a first characteristic dimension. The second region is communicatively coupled with the first region such that the particles can travel between the first region and the second region. The second region has a second characteristic dimension on the order of or not larger than a characteristic length for the particles. For example, the characteristic length may be a particle mean free path and/or a particle size. A system including a first region configured to retain particles in a regular state and a second region communicatively coupled with the first region is also described. The second region is configured such that the particles in the second region are in a nonchaotic state. In some embodiments, the first region has a first characteristic dimension and the second region has a second characteristic dimension less than the first characteristic dimension. The second characteristic dimension may be on the order of or not larger than a particle characteristic length (e.g. particle mean free path and/or particle size).

In some embodiments, the first region and the second region are communicatively coupled such that mass and/or energy is transferable between the first region and the second region. The second region may include a barrier to the transfer of particles from the first region. For example, the barrier may an energy barrier and/or an asymmetric physical barrier (e.g. an entropy barrier). For example, the asymmetric physical barrier may include an asymmetric movable part coupled with an aperture between the first region and the second region (e.g. a molecular chain connected to an aperture that function in a manner analogous to a gate that moves at one side). In another example, the energy barrier may include an electric field for the particles including charge carriers or a gravitational field. In some embodiments, the system includes a third region communicatively coupled with at least the second region. The third region may also be communicatively coupled with the first region such that the particles can travel between the first region and the second region, between the second region and the third region and between the third region and the first region.

A method includes providing an apparatus and providing the particles in the apparatus. The apparatus includes a first region and a second region. The first region is configured to retain particles and has a first characteristic dimension. The second region is communicatively coupled with the first region such that the particles can travel between the first region and the second region. Further, the second region has a second characteristic dimension on the order of or not larger than a characteristic length for the particles. In some embodiments, the method includes studying particle behavior in at least one of the first region or the second region. For example, behavior of the particles in the second (nonchaotic) region may be studied by measuring properties of the first region. In some embodiments, providing the apparatus includes providing a third region communicatively coupled with the first region and the second region. The particles can travel between the first region and the second region, between the second region and the third region, and/or between the third region and the first region.

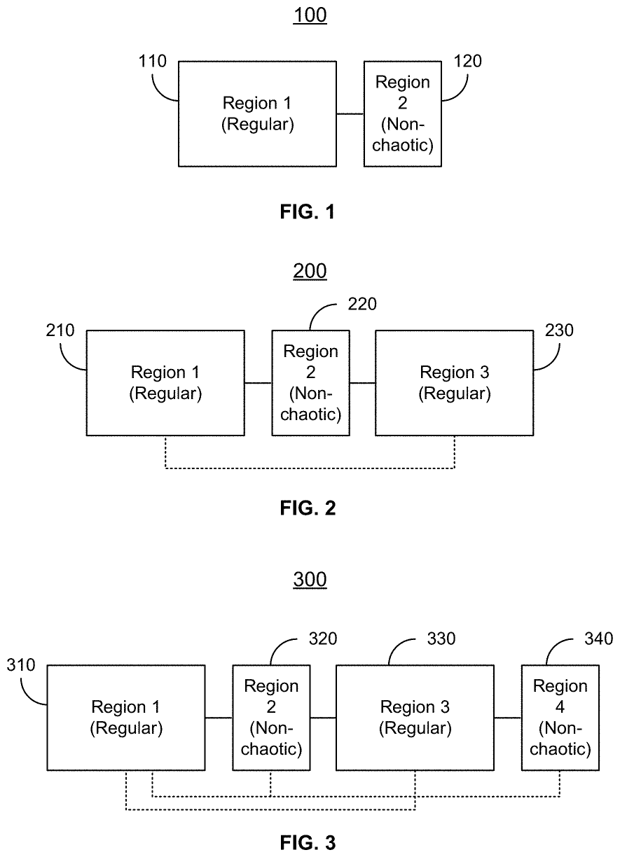

FIG. 1 is a block diagram of an embodiment of system 100 usable in studying nonchaotic behavior. System 100 includes two regions 110 and 120. Particles reside in regions 110 and 120. Regions 110 and/or 120 may thus retain particles therein. For example, regions 110 and 120 may contain gases, liquids, solids, plasmas, Bose-Einstein condensates, or any combination thereof. Region 110 is configured such that the particles therein behave in an ergodic and/or chaotic manner. Stated differently, particles in region 1 are in a regular state. For example, classical statistical mechanics and thermodynamics apply. Consequently, region 110 is configured such that its characteristic dimensions are larger than characteristic lengths for the particles therein. In some embodiments, the characteristic dimension(s) are significantly larger than the characteristic lengths for the particles.

In some embodiments, particles are things (e.g., objects, items, units, packets, or elements) that exist and/or are acted upon by thermal energy or useful energy within a dynamical system. Particles may be atoms, molecules, clusters of atoms or molecules, charge carriers (e.g., electrons, ions, and holes), subatomic particles, fundamental particles, or any component or combination thereof. In some embodiments, region 110 (e.g. a container holding gas atoms or gas molecules or a conductor in which charge carriers reside) is significantly larger than the size of the particle (e.g. a characteristic diameter/size) and/or significantly larger than the mean free path of the particle (e.g. the mean free path of the gas molecule in a container or charge carrier in a conductor). In some embodiments, region 110 is larger than (e.g. larger than, at least twice, at least three multiplied by, at least five multiplied by, or at least ten multiplied by, or at least one hundred multiplied by) the mean free path and/or size of the particle.

Region 120 is communicatively coupled with region 110. Consequently, particles may travel between region 110 and region 120. Mass and/or energy may be transferred between regions 110 and 120. Region 120 is configured such that particles in region 120 are in a nonchaotic (and/or nonergodic) state. The term “nonchaotic” may be used to describe an area, a material, or a device in which, either globally or locally, no extensive particle interaction happens, the particle interaction does not to lead to a random microscopic behavior, or the particles are subject to certain constraints that do not lead to a random microscopic behavior. Region 120 thus has characteristic dimension(s) that are on the order of (e.g. not more than twice) or smaller than the characteristic length for the particles contained therein. In some embodiments, the characteristic dimensions may be not larger than the characteristic length of the particle. For example, the characteristic dimension(s) of region 120 may be not larger than the particle mean free path and/or particle size. In some embodiments, the characteristic dimension(s) of region 120 may be on the order of or smaller than (e.g. not more than two times, not more than, not more than half, not more than one-fifth, not more than one-tenth, or not more than one-hundredth) of the particle mean free path and/or particle size.

Region 120 may also include a barrier to the transfer of particles from and/or to region 110. Thus, although particles may be exchanged between regions 110 and 120, there is some resistance or interruption to particles moving between region 110 and region 120, and (in some embodiments) vice versa. As a result of nonchaoticity in region 120, the steady state may be different from that of a chaotic system. The barrier may be an energy barrier (e.g. a gravitational, electric, and/or magnetic field that opposes the direction of motion) and/or an asymmetric physical barrier (e.g. an entropy barrier). For example, the asymmetric physical barrier may include an asymmetric filter and/or an asymmetric movable part coupled with an aperture between the first region and the second region (e.g. a molecular chain connected to an aperture that function in a manner analogous to a gate that opens at one side). In another example, the energy barrier may include an electric field for the particles including charged particles or a gravitational field.

Region 110 having particles in a regular state and region 120 having particles in a nonchaotic state are communicatively coupled. As such, the state of the particles in region 120 may be interrogated by measuring properties of region 110. In some embodiments, measurements of pressure, temperature, density, current, voltage, and/or volume of the particles in region 110 may provide information on particles in the nonchaotic state in region 120. For example, the density of particles in region 120 may be inferred from the density of particles in region 110. Thus, using system 100, the behavior of particles in the nonchaotic and/or nonergodic states in region 120 may be studied by measuring properties of particles in the regular state in region 110. As such, investigation of nonchaotic states may be facilitated. Further, operation of system 100 may provide other benefits.

FIG. 2 is a block diagram of an embodiment of system 200 usable in studying nonchaotic behavior. System 200 includes regions 210, 220, and 230. Regions 210 and 220 are analogous to regions 110 and 120, respectively. Thus, region 210 is configured such that the particles therein behave in an ergodic and/or chaotic manner and are in a regular state. Region 210 has characteristic dimension(s) that are larger than the characteristic length(s) (e.g. size and/or mean free path) of the particles. Region 220 is communicatively coupled with region 210. Consequently, particles may travel between region 210 and region 220. Mass and/or energy may be transferred between regions 210 and 220. Region 220 is configured such that particles in region 220 are in a nonchaotic (and/or nonergodic) state. Region 220 has characteristic dimension(s) that are on the order of or smaller than the characteristic length (e.g. size and/or mean free path) for the particles contained therein. Similarly, region 220 also includes a barrier to the transfer of particles from region 210. Thus, although particles may be exchanged between regions 210 and 220, there is some resistance to and/or interruption in the particles moving from region 210 to region 220 and/or from region 220 to region 210. The barrier may be an energy barrier (e.g. a gravitational, electric, and/or magnetic field that opposes the direction of motion from the first region to the second region) and/or an asymmetric physical barrier (e.g. an entropy barrier).

System 200 also includes region 230 that is analogous to region 210. In particular, particles in region 230 are in a regular (e.g. chaotic and/or ergodic) states. Region 230 has characteristic dimension(s) that are larger than the characteristic length(s) (e.g. size and/or mean free path) of the particles. However, the dimensions of region 230 may be the same as or different from the dimensions of region 210. Region 230 is communicatively coupled with region 220. Thus, particles, mass, and/or energy may be transferred between region 230 and region 220. In some embodiments, there is a barrier to movement of particles from region 220 to region 230. In such embodiments, the barrier may be an energy barrier and/or an entropy barrier (e.g. an asymmetric physical barrier). However, in other embodiments, there is no barrier to the movement of particles from region 220 to region 230. In some embodiments, region 230 is communicatively coupled to region 210. This is indicated by the dashed line in FIG. 2. Thus, particles, mass, and/or energy may also be transferred between region 210 and region 230 in such embodiments.

Regions 210 and 230 configured to have particles in a regular state and region 220 configured to have particles in a nonchaotic state are communicatively coupled. As such, the state of the particles in region 220 may be interrogated by measuring properties of region(s) 210 and/or 230. In some embodiments, measurements of pressure, temperature, density, flow rate, current, voltage, and/or volume of the particles in region(s) 210 and/or 230 may provide information on particles in the nonchaotic state in region 220. For example, the crossing rate of particles in region 220 may be inferred from the density of particles in region 210 and/or 230. Thus, using system 200, the behavior of particles in the nonchaotic and/or nonergodic states in region 220 may be studied by measuring properties of particles in the regular state in region(s) 210 and/or 230. As such, investigation of nonchaotic states may be facilitated. Further, operation of system 200 may provide other benefits.

Multiple regular regions analogous to region(s) 110, 210, and/or 230 may be communicatively coupled with regions analogous to region(s) 120 and/or 220 in different configurations. For example, FIG. 3 depicts a block diagram of an embodiment of system 300 usable in studying nonchaotic behavior. System 300 includes regions 310, 320, 330, and 340. Regions 310, 320, and 330 are analogous to regions 210, 220, and 230, respectively. Thus, regions 310 and 330 are configured such that the particles therein behave in an ergodic and/or chaotic manner and are in a regular state. Regions 310 and 330 each has characteristic dimension(s) that are larger than the characteristic length(s) (e.g. size and/or mean free path) of the particles. Region 320 is configured such that particles in region 320 are in a nonchaotic (and/or nonergodic) state. Region 320 has characteristic dimension(s) that are on the order of (e.g. not more than twice or not more than the characteristic length) or smaller than the characteristic length (e.g. size and/or mean free path) for the particles contained therein. Region 320 is communicatively coupled with regions 310 and 330. Consequently, particles, mass, and/or energy may travel between region 310 and region 320 and between regions 320 and 330. Similarly, region 320 also includes a barrier to the transfer of particles to and/or from region 310. The barrier may be an energy barrier (e.g. a gravitational, electric, and/or magnetic field that opposes the direction of motion from the first region to the second region) and/or an asymmetric physical barrier (e.g. an entropy barrier). Also shown is region 340 that is analogous to region 320. Thus, region 340 may have characteristic dimensions on the order of or smaller than the particle mean free path and/or particle size. Region 340 may or may not have a barrier to the motion of particles to region analogous to that of region 320. In some embodiments, regions 310, 320, 330, and 340 are communicatively coupled such that particles, mass, and/or energy may be transferred between regions 310, 320, 330, and/or 340.

Regions 310 and 330 configured to have particles in a regular state and regions 320 and 340 configured to have particles in a nonchaotic state are communicatively coupled. As such, the state of the particles in region 320 and/or 340 may be interrogated by measuring properties of region(s) 310 and/or 330. Thus, using system 300, the behavior of particles in the nonchaotic and/or nonergodic states in region(s) 320 and/or 340 may be studied by measuring properties of particles in the regular state in region(s) 310 and/or 330. As such, investigation of nonchaotic states may be facilitated. Further, operation of system 300 may provide other benefits. For example, the barrier parameters can be adjusted, so that the measurement can be performed under different conditions.

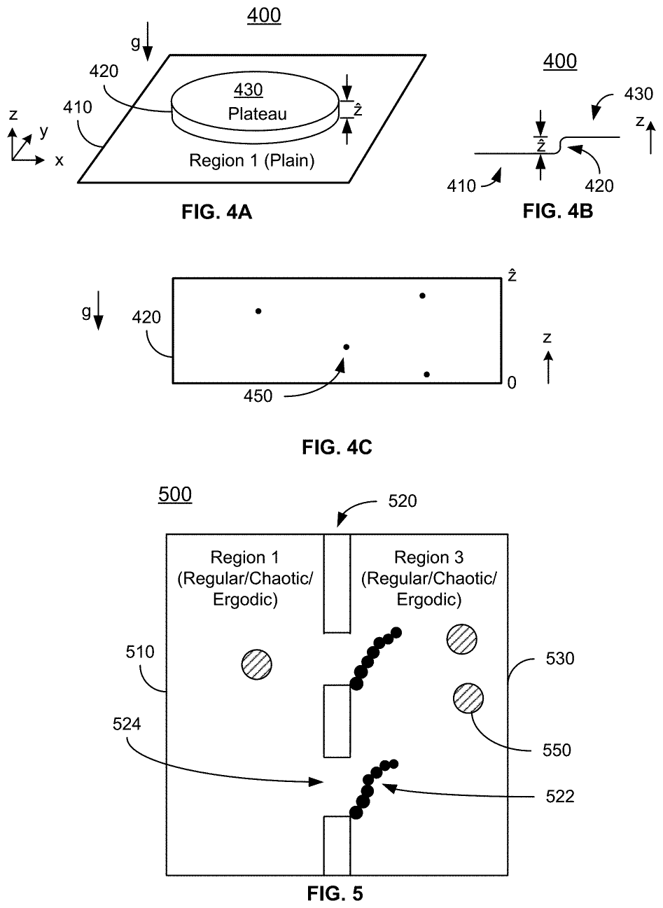

FIGS. 4A, 4B, and 4C are diagrams depicting perspective and side views of an embodiment of 400 system usable in studying nonchaotic behavior. FIGS. 4A-4C are not to scale. System 400 includes regions 410, 420, and 430 that are analogous to regions 210, 220, and 230, respectively. FIG. 4A is a perspective view of system 400. FIG. 4B is a side view showing the variation of system with distance from the central portion of region 430 (i.e. radius, r). FIG. 4C depicts the variation of region 420 around region 430. Regions 410 and 430 are configured such that particles 450 (labeled and shown in FIG. 4C only) therein behave in an ergodic and/or chaotic manner and are in a regular state. Regions 410 and 430 each has characteristic dimension(s) that are larger than the characteristic length(s) (e.g. size and/or mean free path) of the particles. Region 420 is communicatively coupled with region 410 and region 430. Consequently, particles 450 may travel between region 410 and region 420 and between regions 420 and 430. Particles 450 may thus be transferred between regions 410 and 430. Although particular shapes (e.g. rectangular and circular) for regions 410, 420, and 430 are shown, other shapes are possible.

Region 420 is configured such that particles in region 420 are in a nonchaotic (and/or nonergodic) state. Thus, in some embodiments, particles 450 in region 420 may form a Knudsen gas. Region 420 has characteristic dimension(s) (e.g. height \hat{z}) that are on the order of or smaller than the characteristic length (e.g. size and/or mean free path) for the particles contained therein. Similarly, region 420 also includes a barrier to the transfer of particles from region 410. Thus, although particles may be exchanged between regions 410 and 420, there is some resistance to and/or interruption in particles moving from region 410 to region 420 and/or from region 420 to region 410. The barrier may be an energy barrier (e.g. a gravitational, electric, and/or magnetic field that opposes the direction of motion from the first region to the second region).

More specifically, region 410 may be considered to be a plain (or lower) region 410, region 430 is a raised region or plateau 430, and region 420 is a transition step 420. Transition step 420 has a height \hat{z} that is less than the mean free path of particles 450. System 400 is an ideal-gas type system. A large number of elastic particles 450 randomly move in the horizontal x-y dimension. A uniform gravitational field (g) is along the out-of-plane −z direction. The central area (region 430) is higher, which will be referred to as “plateau”. The surrounding lower area (region 410) will be referred to as “plain”. The plateau height (\hat{z}) can be changed by a lifting force on the plateau, F_{G}. The total particle number N=N_{P}+N_{G} is constant, with subscripts “P” and “G” indicating the surrounding plain (region 410) and the central plateau (region 430), respectively. The plain area (A_{P}) can be adjusted by the in-plane pressure (P) at the outer boundary; the area (A_{G}) of plateau 430 is fixed. The thermodynamic driving forces under investigation are P and F_{G}, with the conjugate variables being −A_{P} and \hat{z}, respectively. It is assumed that i) the particle motion is frictionless; ii) the changes of \hat{z} and A_{P} are reversible; iii) the transition step region 420 is smooth; i.e., as particles move across it, no energy is dissipated; and iv) the system boundary is a perfect heat exchanger, and the environment is an infinitely large heat reservoir with a constant average particle kinetic energy (K̅). Moreover, v) the system selected for study has \hat{z} much smaller than the plain and plateau sizes; when g=0, \hat{z} has little direct influence on the particle distribution.

As shown in FIG. 4A, plateau 430 and plain 410 are two large areas separated by the transition step (region 420) and are respectively dominated by F_{G} and P. The gravitational force is directional and asymmetric in transition step 420. Variations in A_{P} or \hat{z} would cause particle redistribution across the transition step 420, resulting in the exchange of particle kinetic energy (K) with the environment. A_{P} and \hat{z} can be adjusted reversibly and independently, with a constant K̅. If \hat{z} is much less than the particle mean free path (λ_{F}), the transition step 420 would be nonchaotic. In this example, the region 420 includes an energy barrier. Because the transition step 420 is enclosed in the interior, pressure (P), area change (dA_{P}), force (F_{G}), and displacement (d\hat{z}) can be readily measured at the system outer boundary.

The in-plane pressure of plain 410 is governed by P·A_{P}=N_{P}·K̅. When the size of transition step 420 is much less than the sizes of plain 410 and plateau 430, the lifting force (F_{G}) on the plateau is approximately F_{G}=mgN_{G}, where m indicates the particle mass.

The plateau-to-plain particle number density ratio (\hat{ρ}) is considerably influenced by the ergodicity and chaoticity of the transition step 420. In the transition step 420 where \hat{z} is much less than the nominal mean free path of particles (λ_{F}), the relevant kinetic energy for particles to overcome the gravitational energy barrier from the plain to the plateau is mostly determined by the z-dimension momentum, in average less than the total particle momentum by a factor of 2.

Plain region 410 and plateau region 430 configured to have particles in a regular state and transition step region 420 configured to have particles 450 in a nonchaotic state are communicatively coupled. Thus, particles 450 in region 420 may form a Knudsen gas. The properties of the Knudsen gas may be desired to be investigated and/or utilized. Because transition step 420 is communicatively coupled with plain 410 and plateau 430, the state of the particles in region 420 may be interrogated by measuring properties of region(s) 410 and/or 430. Thus, using system 400, the behavior of particles in the nonchaotic and/or nonergodic states in transition step region 420 may be studied by measuring properties of particles in the regular state in plain region 410 and/or plateau region 430. The measured properties of region 410 and region 430 include but not limited to pressure, volume, voltage, flow rate, current, and temperature. The behaviors of region 420 under investigation include but not limited to transfer rates of mass, particles, energy, and heat. As such, investigation of nonchaotic states may be facilitated. Further, operation of system 400 may provide other benefits.

The system configuration can be adjusted to measure the properties of regions 410 and region 430 under different conditions. The variation of the system parameters may be in a cycle, as the parameters are changed alternately. In one example, the plateau height (\hat{z}) and the plain area (A_{P}) can be varied. In another example, \hat{z} is first increased, followed by increase of A_{P}. Then, \hat{z} is reduced back to the initial value, and A_{P} is reduced back to the initial value. The works of the lifting force and the in-plain pressure can be measured and compared. In yet another example, region 420 can be included in the interior of region 430, and region 410 and region 430 are connected by a chaotic transition zone (e.g. a wide ramp). For example, region 420 can be vertical-walled traps, with movable trap floors. The trap floors can be connected to region 430 through speed-reduction gears, so that the trap depth proportionally changes with the plateau height. \hat{z} and A_{P} can be adjusted in the same cycle as the previous example. Similarly, the works of the lifting force and the in-plain pressure can be measured or utilized. In these examples, the measurement can also be performed on temperatures in region 410 and region 430, to study or utilize the heat transfer in region 420. As such, the nonchaotic properties of region 420 can be studied or utilized.

FIG. 5 is a diagram of an embodiment of system 500 usable in studying nonchaotic behavior. FIG. 5 is not to scale. System 500 includes regions 510, 520, and 530 that are analogous to regions 210, 220, and 230, respectively. Regions 510 and 530 are configured such that particles 550 (only one of which is labeled) therein behave in an ergodic and/or chaotic manner and are in a regular state. Regions 510 and 530 each has characteristic dimension(s) that are larger than the characteristic length(s) (e.g. size and/or mean free path) of the particles. Region 520 is communicatively coupled with region 510 and region 530. Consequently, particles 550 may travel between region 510 and region 520 and between regions 520 and 530. Thus, particles 550 are also exchanged between regions 510 and 530.

Region 520 is configured such that region 520 is in a nonchaotic (and/or nonergodic) state. Region 520 has characteristic dimension(s) that are on the order of (e.g., not more than twice or not more than) the characteristic length or smaller than the characteristic length (e.g. size and/or mean free path) for particles 550 contained (or passing through) therein. Similarly, region 520 also includes a barrier to the transfer of particles 550 from regions 510 and 530. Although particles may be exchanged between regions 510 and 530 through region 520, there is some resistance or interruption to particles moving between regions 510 and 520 and regions 520 and 530. In the embodiment shown, the barrier is an entropy barrier. More specifically, region 520 may be considered to be a micro-filter having asymmetric physical barriers. Thus, region 520 includes a film having apertures (or micropores) 524 and asymmetric physical barriers 522. For clarity, only one asymmetric physical barrier 522 and only one aperture 524 is labeled in FIG. 5. The characteristic arrival time of particles 550 at micropore apertures 524 is less than the characteristic time of the movement of physical barriers 522. Asymmetric physical barriers 522 may be molecular chains grafted to the surface of micropore apertures 524. Asymmetric physical barriers 522 open toward region 530, but not toward region 510. Thus, barriers 522 are asymmetric. In some embodiments, apertures 524 have a width on the order of ten Angstroms or less. Thus, apertures 524 and asymmetric physical barriers 522 have characteristic dimensions on the order of (e.g. not more than twice) or not more than the characteristic length (e.g. size and/or mean free path) for particles 550.

Regions 510 and 530 are configured to have particles in a regular state, while microfilter region 520 is configured to have particles 550 in a nonchaotic state. Because regions 510, 520, and 530 are communicatively coupled, particles 550 may travel between regions 510, 520, and 530. However, asymmetric physical barriers 522 in conjunction with apertures 524 allow for nonchaotic behavior of particles 550 in region 520. The properties of region 520 may be desired to be investigated and/or utilized. Because microfilter region 520 is communicatively coupled with chaotic/ergodic regions 510 and 530, the state of the particles in and due to region 520 may be interrogated by measuring properties of region(s) 510 and/or 530. For example, temperature, density, and pressure of particles 550 may be measured. Thus, using system 500, the behavior of particles in the nonchaotic and/or nonergodic states in region 520 may be studied by measuring properties of particles in the regular state in region(s) 510 and/or 530. As such, investigation of nonchaotic states may be facilitated. Further, operation of system 500 may provide other benefits.

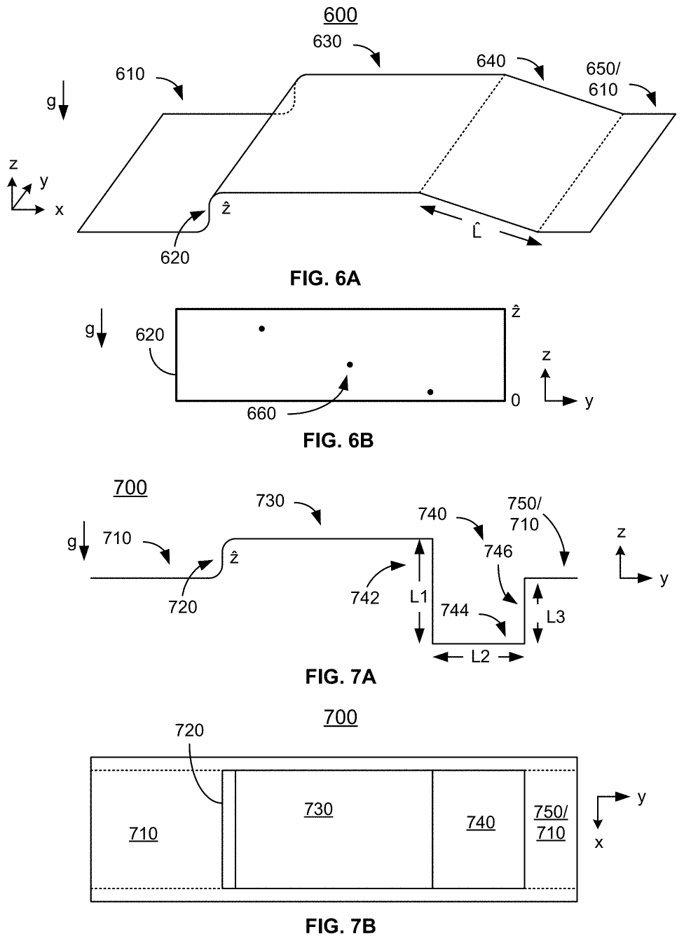

FIGS. 6A-6B are diagrams of an embodiment of system 600 usable in studying nonchaotic behavior. FIGS. 6A and 6B are not to scale. System 600 includes regions 610, 620, 630, 640, and 650. Regions 610, 620, and 630 are analogous to regions 210, 220, and 230, respectively. More specifically, regions 610, 620, and 630 are analogous to regions 410, 420, and 430, respectively. Region 650 is analogous to region 610. Region 640 is a chaotic transition zone between regions 630 and 650. In some embodiments, region 650 is communicatively coupled with region 610. Thus, particles may flow between regions 650 and 610. Regions 610, 630, 640, and 650 are configured such that particles 660 (only shown in FIG. 6B and only one of which is labeled) therein behave in an ergodic and/or chaotic manner and are in a regular state. Regions 610, 630, 640, and 650 each has characteristic dimension(s) that are larger than the characteristic length(s) (e.g. size and/or mean free path) of the particles. For example, length L of region 640 is longer than the mean free path of particles 660. Region 620 is communicatively coupled with region 610 and region 630. Consequently, particles 660 may travel between regions 610, 620, 630, 630, and 650/610.

In one embodiment, system 600 includes a lower plain 610, a vertical transition step 620, an upper plateau 630, a long (chaotic) ramp 640, and a lower plain 650 on the right-hand side. A number of elastic particles randomly move in the system. There is no long-range force among the particles. The plateau height, i.e., the step size (\hat{z}), is much less than the mean free path of the particles (λ_{F}). The ramp size, \hat{L}, is much larger than λ_{F}. The in-plane direction from right to left is denoted by x; the in-plane direction vertical to x is denoted by y; the out-of-plane direction is z. The system is in a uniform gravitational field along −z, with the gravitational acceleration being denoted by g.

A MC simulation system may be performed for system 600 to simulate operation of system 600. Such a MC simulation reflects the surface of particle movement in FIGS. 6A-6B and consisted of a rectangle box and a number of elastic particles. From left to right, it contains the left plain 610, the step 620, the plateau 630, the ramp 640, and the right plain 650. The upper and the lower boundaries of the simulation box were rigid specular walls. The left and the right boundaries used periodic boundary condition. The width of the box (w₀), i.e., the distance between the upper and the lower boundaries, was 500 Å. The length of plain 610 was 50 Å. The plateau length was 100 Å. The transition step size, \hat{z}, was 5 Å. The ramp length, \hat{L}, was 500 Å. The length of plain 650 was 50 Å.

The particles in the transition step 620 were subjected to a gravitational force pointing to in the −z direction. The particles in ramp region 640 were also subjected to a gravitational force pointing to down. The particle movement in the plains 610 and 650 and on plateau 630 was not affected by the gravitational force. The particle-particle collision and the particle-wall collision were elastic. The main system parameters are listed below: the total particle number: N=500; the effective temperature: T=1000 K; the particle mass: m=1 g/mol=1.66×10⁻²⁷ kg; the particle radius: r=1 Å=10⁻¹⁰ m; the timestep: Δt₀=1 fs=10⁻¹⁵ s; the average particle kinetic energy on the plain: K̅=k_{B}T=1.38×10⁻²⁰ J, where k_{B} is the Boltzmann constant.

Initially, all the particles were randomly generated on the plain, with the initial velocities following the two-dimensional (2D) Maxwell-Boltzmann distribution. The moving direction is random. If the amplitude of the total initial x-dimension momentum of all the particles was larger than about 10⁻³ p₀, the configuration would be rejected, where p₀=\sqrt{2 mk_{B}T/π}. All the testing cases discussed below used the same initial condition.

For each testing case, the effective gravitational acceleration in the transition step was

$$g = \frac{\overline{K}}{m \cdot \hat{z}} \cdot \hat{φ} ,$$

and the effective gravitational accelerations in the ramp was

$${g}_{r} = \frac{\overline{K}}{m \cdot \hat{L}} \cdot \hat{φ} ,$$

where \hat{φ}=0, 0.1, 0.2, 0.3, 0.4, 0.5, 0.7, 1.0, 1.5, or 2.0. The Boltzmann factor is

$${δ}_{0} = exp ( - \frac{m g \hat{z}}{{k}_{B} T} ) .$$

It can be seen that mg\hat{z}=mgᵣ\hat{L}.

Every time when a particle crossed the periodic boundary at the left-hand side of the simulation box (the left boundary of plain 610), the timestep, the particle identification number (ID), the particle moving direction, and the particle velocity were recorded. For every 200 timesteps, the position and the velocity of every particle were recorded.

The overall number of the particles crossing the left-hand side boundary was calculated every 5000 timesteps. The average flux from timestep 2×10⁴ to timestep 1.5×10⁵ is denoted by j. The normalization factor of j was taken as

$${j}_{0} = \frac{N}{{d}_{0}} {\overline{v}}_{x} Δ t ,$$

where Δt is 5000 time steps, v̅ₓ=\sqrt{2 k_{B}T/(πm)} is the nominal average x-dimension particle velocity, and d₀=705 Å is the total length of the simulation box.

For every 200 timesteps, the average x-component and y-component of particle momentums in the entire system were computed as

$${\overline{p}}_{x} = \frac{1}{N} \sum m {v}_{x} and {\overline{p}}_{y} = \frac{1}{N} \sum m {v}_{y} ,$$

where Σ indicates summation of all the particles, and vₓ and v_{y} are respectively the x-component and y-component of particle velocities. For every 5000 timesteps, all the particles crossing the left-hand side boundary from right to left were used to calculate the effective partial pressure along the x direction,

$${P}_{+} = \frac{1}{{w}_{0} Δ t} \sum {mv}_{x +} ,$$

where vₓ₊ is the x-component of velocity of a particle moving from right to left across AA′, and Δt is 5000 timesteps. For every 5000 timesteps, all the particles crossing the left-hand side boundary (AA′) from left to right were used to calculate the effective partial pressure along the −x direction,

$${P}_{-} = \frac{1}{{w}_{0} Δ t} \sum {mv}_{x -} ,$$

where x-component of velocity of a particle moving from left to right across AA′. Average P₊ and P₋ were calculated from timestep 2×10⁴ to timestep 1.5×10⁵. The net pressure across AA′ is defined as ΔP=P₊−P₋. Pressure can be normalized by P₀=Nk_{B}T/A₀, where A₀ is the simulation box area. The average steady-state particle speeds in region 630 and regions 610/650 may be different from each other by more than 5%. The steady-state flow rate j (about 20% of j₀ when mg\hat{z}/K̅=0.2) and net pressure ΔP (about 22% of P₀ when mg\hat{z}/K̅=0.2) measured in regions 610 and 650 reflect the movement of particles 660 in region 620.

Regions 610, 630, 640, and 650 are configured to have particles in a regular state, while transition step region 620 is configured to have particles 660 in a nonchaotic state. The properties of region 620 and system 600 may be desired to be investigated and/or utilized. Because region 620 is communicatively coupled with chaotic/ergodic regions 610, 630, 640, and 650, the state of the particles in and due to region 620 may be interrogated by measuring properties of region(s) 610, 630, 640, and/or 650. Thus, using system 600, the behavior of particles in the nonchaotic and/or nonergodic states in region 620 may be studied by measuring properties of particles in the regular state in region(s) 610, 630, 640 and/or 650. As such, investigation of nonchaotic states may be facilitated. Further, operation of system 600 may provide other benefits. The measurement can be performed at various conditions as the system parameters are changed. The system parameters include but not limited to temperature, the plain area, the plateau height, and the force field.

FIGS. 7A-7B are diagrams of an embodiment of system 700 usable in studying nonchaotic behavior. FIG. 7A depicts a side view, while FIG. 7B depicts a plan view. FIGS. 7A and 7B are not to scale. System 700 includes regions 710, 720, 730, 740, and 750 that are analogous to regions 610, 620, 630, 640, and 650, respectively. Regions 710, 730, 740, and 750 are configured such that particles therein behave in an ergodic and/or chaotic manner and are in a regular state. Regions 710, 730, 740, and 750 each has characteristic dimension(s) that are larger than the characteristic length(s) (e.g. size and/or mean free path) of the particles. However, instead of a ramp, region 740 is formed by steps 742 and 746 connected by flat region 744. The lengths L1, L2, and L3 of regions 742, 744, and 746, respectively, are longer than the mean free path of particles in system 700. Thus, the “ramp” region 640 or 740 may have different configurations while maintaining the regular state of particles therein. Region 720 is communicatively coupled with region 710 and region 730. Consequently, particles may travel between regions 710, 720, 730, 740, and 750/710. System 700 operates in a manner analogous to system 600. Thus, the behavior of particles due to nonchaotic region 720 may be investigated or utilized by the properties of regions 710, 730, 740, and/or 750.

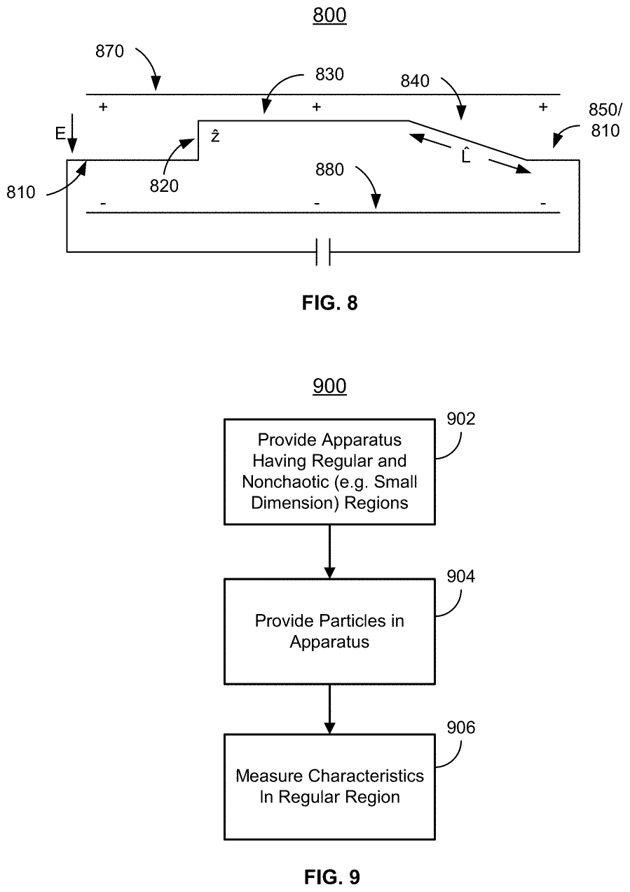

Similar phenomenon can be realized by the charge carriers in a condensed matter. For instance, in metals, the mean free path of conduction electrons (λₑ) is 20˜50 nm; the Fermi velocity (v_{F}) is on the scale of 10⁶ m/s, and the density of the conduction electrons (ρₑ) is a few 10⁹ C/m³. Referring to FIG. 8, a nanowire or nanolayer has an asymmetric structure with a small nano-step 820 at one end and a wide slope 840 at the other end, in an external electric field (E) generated by electret plates 870 and 880. Regions 810, 830, 840, and 850 are regions in which particles (e.g. charge carriers in the nanowire) behave in a regular, chaotic ergodic manner. Transition step 820 is a nonchaotic region. The nano-step size (2) should be much less than λₑ; the slope size (\hat{L}) should be much larger than λₑ. Similar to j₀, the reference current density could be taken as jₑ₀=ρₑv_{F}/2, on the scale of 10¹⁵ A/m². The maximum current density might be a fraction of jₑ₀, around 10¹⁴ A/m². A number of nano-steps can be placed in tandem or in parallel, to amplify the current or to reduce the requirement on E.

Using systems 800, the properties of particles due to region 820 may be studied based on measurements for regions 810, 830, 840, and/or 850/810. Systems 600 and 700 may be utilized similarly. For example, current may be measured and characteristics of step 820 may be inferred. As such, investigation of nonchaotic states may be facilitated. Further, operation of system 800 may provide other benefits.

FIG. 9 is a flow-chart depicting an embodiment of method 900 usable in studying nonchaotic behavior. For simplicity, only certain steps are depicted. Further, steps include substeps.

An apparatus is provided, at 902. 902 may thus include configuring systems such as system(s) 100, 200, 300, 400, 500, 600, 700, and/or 800. Particles are provided in the apparatus, at 902. In some embodiments, 902 includes introducing particles (e.g. a gas) and preparing the state of the gas (e.g. adjusting temperature and/or volume) as desired. In embodiments, such as system 800, particles (e.g. charge carriers) may be introduced by utilizing the appropriate conductive materials having the charge carriers therein. In some embodiments, particle behavior is studied by measuring characteristics in regions in which particles are in a regular state (e.g. are in a chaotic and/or ergodic state).

Thus, using method 900, systems that include regular and nonchaotic regions may be formed. For example, method 900 forms systems having regions with dimensions that are large compared to particle characteristic length(s) that are communicatively coupled with regions having dimension(s) that are approximately the same size or smaller than the particle characteristic lengths. Systems 100, 200, 300, 400, 500, 600, 700, and/or 800 may thus be provided. Consequently, the behavior of particles in nonchaotic regions may be examined by measuring characteristics of the regular regions. Thus, the study of particles in nonchaotic regions may be facilitated.

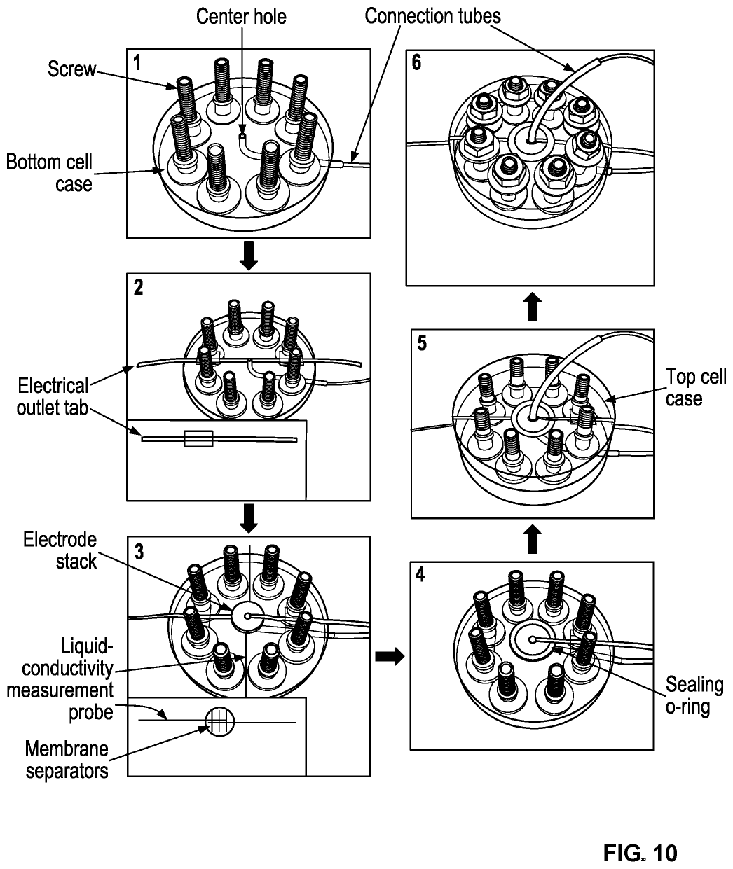

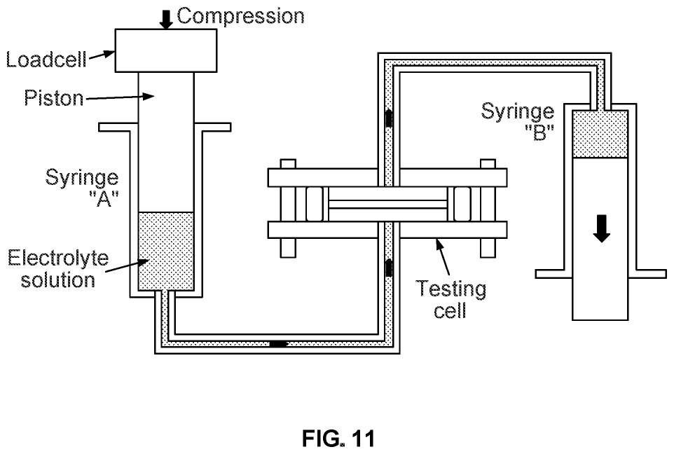

For example, FIGS. 10-11 depict embodiments of an apparatus usable in investigating the behavior of particles in nonchaotic systems. In this sample application, the mismatch between the charge efficiency (Λ) and the ion-concentration sensitivity of electric potential (|ε′_{c}|) of large ions adsorbed in charged micropores may be investigated. Although described in the context of specific materials, processes, and/or components, other materials, processes, and/or components may be used in other embodiments.

Spectracarb-2225 Type-900 nanoporous carbon was processed into 15.88-mm-diameter electrode discs and dried in a gravity convection oven (VWR, 1330GM) at 120° C. for 24 hours. The disc mass (mₑ) was around 25 mg. Two carbon discs were immersed in 20 mL electrolyte solution in a 20-mL vial in a vacuum oven (VWR, Shel-Lab 1410) at 94.8 kPa for 5 min. The electrolyte was cesium pivalate (CsPiv). The effective nanopore size of the carbon electrodes (˜1 nm) in this embodiment was slightly larger but less than two times of the effective pivalate ion size (˜0.7 nm), so that in the quasi-one-dimensional nanopore environment, the movement of adsorbed ions was restricted. Membrane separators (Dreamweaver, Titanium 30) were cut into 17.46-mm-diameter discs and soaked in the same electrolyte solution for 10 min. Two spacer rings were cut from a 415-μm-thick polycarbonate film (McMaster, 85585K15) by 7.14-mm-inner-diameter and 15.88-mm-outer-diameter punch heads.

Two 25.4-mm-thick 76.2-mm-diameter polyacrylic discs (McMaster, 1221T63) were used as cell cases. Eight equally spaced through-holes were drilled by using a Palmgren drill press (McMaster, 28015A51), with a 7.14-mm-diameter drill bit (McMaster, 2901A126). The center-to-center diagonal distance was 50.8 mm. A center hole was drilled on each cell case by using a 3.18-mm-diameter drill bit (McMaster, 2901A115) for liquid replacement.

External connection tubes were fabricated by fitting 200-mm-long 0.50-mm-inner-diameter 1.52-mm-outer-diameter ethylene-vinyl acetate (EVA) tubes (McMaster, 1883T1) into 50-mm-long poly(vinyl chloride) (PVC) tubes (McMaster, 5231K124), with epoxy adhesive (J-B Weld, McMaster, 7605A18) applied at the tube interfaces. After curing at ambient temperature (T) for 10 h, a connection tube was inserted into the center hole of the top/bottom cell case, secured by epoxy adhesive. A 0.6-mm-diameter needle (BD PrecisionGlide, 305194) was tightly pressed into the EVA tubing, with the other end connected to a 1-mL syringe (BD, 309659).

A pyrolytic graphite sheet (Panasonic, EYG-S121803) was cut into 1.5×20 mm strips by a stainless-steel razor blade (McMaster, 3962A48). A 25-μm-thick nickel foil (MTI, MF-NiFoil-25u) was cut into 2×30 mm strips, followed by repeated flattening in a rolling mill (Durston, DRM F150) with a 20-μm gap. Electrical outlet tab was produced by attaching a graphite strip to a nickel strip using a 4-mm-wide Kapton polyimide tape (McMaster, 7648A32), affixed on the bottom cell case, with the overlapping length of ˜10 mm.

A liquid-conductivity measurement probe was fabricated by using two 0.5-mm-wide 50-mm-long nickel strips 1 mm apart from each other, with the gage length of ˜10 mm. The strips were cut from the aforementioned nickel foil and repeatedly flattened by the rolling mill through a 20-μm gap. The strips were fixed together in parallel by three 0.8-mm-wide Kapton tapes. The probe was sandwiched in between the two membrane separator discs.

The cell assembling procedure is shown in FIG. 10. Stainless steel socket head screws (McMaster, 92196A821) were fit into the through-holes in the bottom cell case, with 1.62-mm-thick nylon plastic washers (McMaster, 95606A420). Two electrical outlet tabs were affixed onto the edge of the bottom cell case by using Kapton polyimide tapes (McMaster, 7648A32). The positive electrode disc was placed at the center of the cell case, covered by a separator-probe sandwich and a negative electrode disc. The tab was adjusted to ensure an adequate electrical connection. The electrode stack was covered by two layers of spacer rings, to reduce the free space and to enhance the electrical contact. Two layers of nylon plastic shims (˜0.785 mm thick, McMaster 90295A450) were added to the screws on the bottom cell case. Before placing the top cell case, the electrode stack had been enclosed by a Viton Fluoroelastomer sealing o-ring (McMaster, 8297T174). Stainless steel nuts (McMaster, 91849A029) were fastened on the screws with 1.62-mm-thick nylon plastic washers (McMaster, 95606A420), by a L-key (McMaster, 5503A22) and a wrench (McMaster, 7152A812), until the shims contacted the top and bottom cell cases. Excess solution was extracted by the syringes via the connection tubes.

After the cell was assembled, the electrical outlet tabs were connected to a Neware CT-ZWJ-4S-T Analyzer. All the cells were pre-cycled between 0 to 0.8 V at 0.1 mA for 20 cycles. Cells with the coulombic efficiency lower than 98% or the internal impedance higher than 50Ω were rejected. Coulombic efficiency was defined as the ratio of discharge capacity to charge capacity of ε−Q cycle, where E is the cell potential and Q is the electrode charge. Internal impedance was calculated from the cell potential change before and after a known current is applied. The prepared cell was tested in charge-discharge cycles, with a constant charging-discharging rate of 0.1 mA. The cell potential was continuously monitored. Charging was stopped regularly to measure the cell potential (ε). At each stop, the cell was rested for 1 min; E was defined as the open-circuit voltage at the end of the resting period. To measure the liquid conductivity (\tilde{μ}), the embedded liquid-conductivity measurement probe was connected to a Hanna HI5321-01 Electrical Conductivity Meter by copper wires. The conductivity was recorded at the same time as the cell potential.

On each cell, the measurement of E and u was repeated for various initial electrolyte concentrations. The initial CsPiv concentrations were 10 mM, 12 mM, 14 mM, and 16 mM. For each condition, three nominally identical cells were tested. After a charging measurement was completed, the liquid phase was replaced by another solution of the same electrolyte but a slightly different concentration (c). Liquid replacement involves generating a slow constant-concentration flow for a certain period of time, until a new equilibrium is reached. It could precisely adjust the electrolyte concentration, with minimum influence on other cell components, such as the electrode stack and the electrical connections. FIG. 11 diagrammatically depicts the liquid replacement system. It is equivalent to changing the liquid volume with an osmotic piston. The testing cell was first connected to two 60-mL syringes (“A” and “B”). Syringe “A” contained the electrolyte solution to be filled into the cell. It was compressed by an Instron-5582 machine, to generate a flow with a constant rate of 4 mL/min for 15˜20 minutes, until the liquid conductivity inside of the cell was stabilized at the new level. The liquid conductivity was continuously monitored by the measurement probe embedded in the cell. Outflow electrolyte solution was collected by syringe “B” on the other side. After liquid replacement, the cell was cycled again for 20 cycles between 0 to 0.8 V. Cells that failed to meet the criteria of coulombic efficiency (>98%) and internal impedance (<50Ω) would be abandoned. Similar cell potential and \tilde{μ} measurement was conducted with the new liquid phase. The measurement was repeated for multiple electrolyte concentrations. Ambient temperature was ˜23° C. for all the tests.

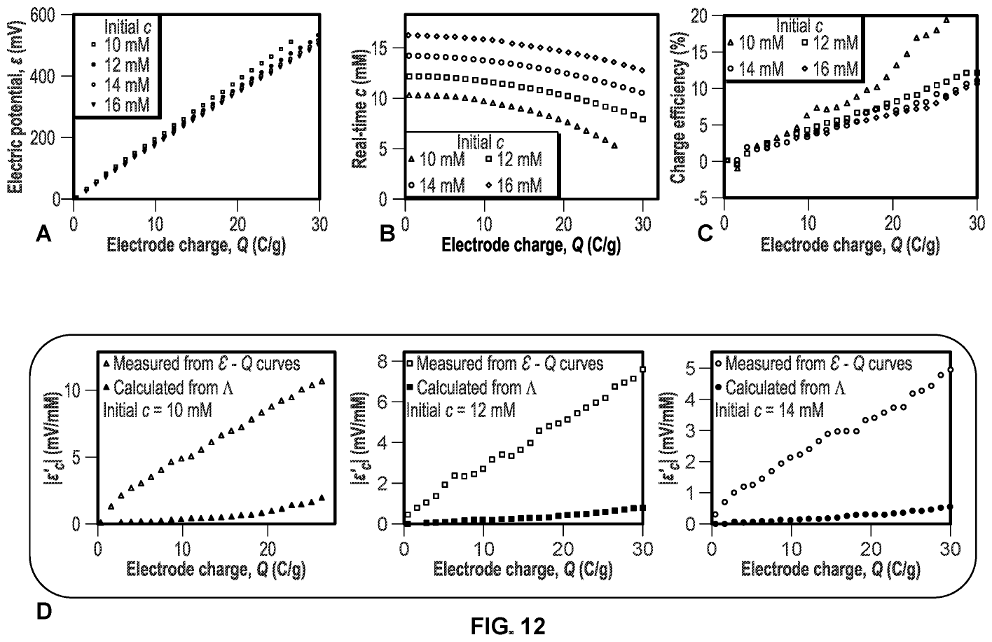

FIG. 12 indicates typical experimental data. The specific electrode charge was obtained as Q=3.6 I/t_{c}/mₑ, where 3.6 is the factor accounting for unit conversion, I is the charging current in mA, t_{c} is the charging time in hr, and mₑ is the electrode mass in gram. For CsPiv, the electrolyte concentration, c, was related to the measured \tilde{μ} by using the calibration curve: c=0.1664\tilde{μ}²+1.2816\tilde{μ}−0.0934. The units of c and \tilde{μ} are mM and mS/cm, respectively. The calibration curves were measured by using the setup shown in FIG. 11. Liquid replacement was carried out for 15˜20 min with solution of known electrolyte concentration (c), until \tilde{μ} has converged. The measurement of \tilde{μ} was repeated at various c: 1 mM, 2 mM, 4 mM, 6 mM, 8 mM, 10 mM, 20 mM, 30 mM, 40 mM, and 50 mM.

The cell volume was V_{cell}=A_{c}d_{c}, with A_{c}=197.9 mm² being the cross-sectional area of electrode stack and d_{c}=0.74 mm the thickness of cell cavity. The solid volumes of carbon (V_{C}) and membrane separators (V_{SP}) were calculated from their mass densities: V_{C}=mₑ/ρ_{C} and V_{SP}=m_{SP}/ρ_{SP}, with ρ_{C}=2.2 g/cm³ being the density of carbon, m_{SP} the mass of separators, and ρ_{SP}=1.6 g/cm³ the density of ligament material. The liquid volume was taken as V_{L}=V_{cell}−V_{C}−V_{SP}, typically around 120 μL. Calculation of the charge efficiency followed the established procedure in literature: Λ=ξV_{L}Δc/ΔQ, where ξ is the Faraday constant, Δc is the measured variation in molarity, ΔQ=3.6 IΔt_{c}/mₑ is the change in electrode charge, and Δt_{c} is the duration associated with Δc. The ion-concentration sensitivity of cell potential, |ε′_{c}|, can be obtained from FIG. 12(A): between two adjacent ε−Q curves, at the same Q, the difference in ε is divided by the difference of real-time c (FIG. 12B). It may also be calculated as

$$\frac{2 {k}_{B} T}{{e}_{0} c}$$

Λ using the values of Λ in FIG. 12(C), with e₀ being the elementary charge; to be conservative, c is taken as the lower bound of the electrolyte concentration involved in the calculation.

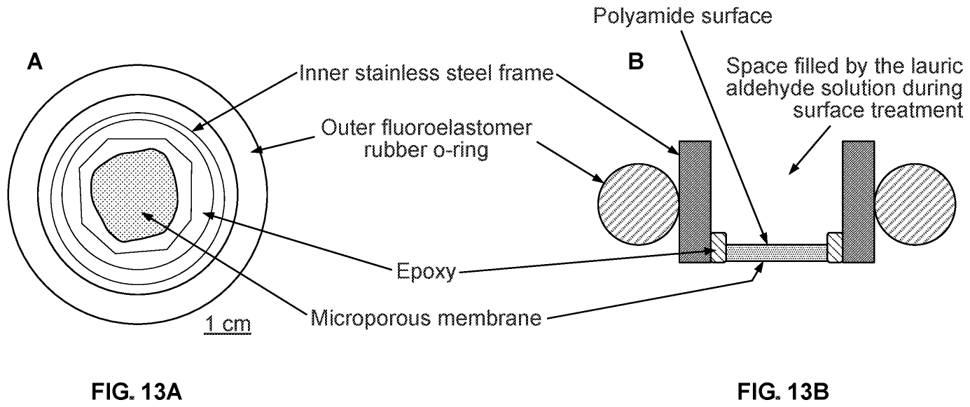

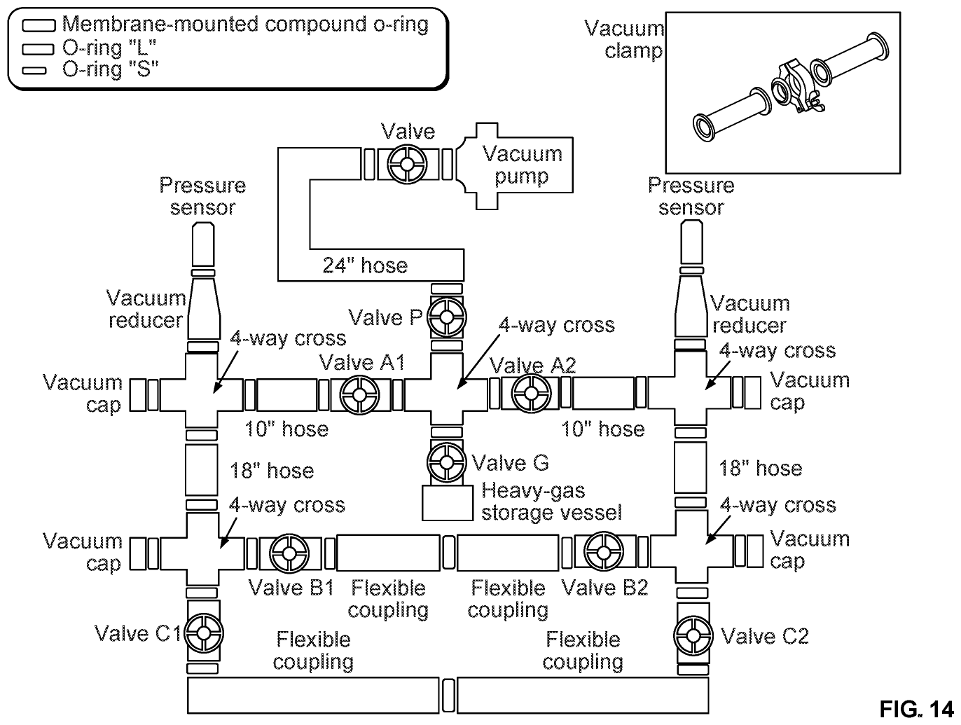

FIGS. 13A-14 depict embodiments of an apparatus usable in investigating the behavior of particles in nonchaotic systems. FIGS. 13A-13B depict the membrane, while FIG. 14 depicts an embodiment of an experimental setup usable with the membrane. In this example, the effective gas permeability of an asymmetric microporous membrane was investigated. Thus, a nonchaotic region analogous to region 520 depicted in FIG. 5 may be studied. Although described in the context of specific materials, processes, and/or components, other materials, processes, and/or components may be used in other embodiments.

Toray UTC-82V polyamide (PA) microporous membrane was obtained from Sterlitech. A membrane sample was sectioned by a razor blade, about 1.7 cm large. It was firmly attached to the stainless steel inner frame of a McMaster-4518K63 compound o-ring (FIGS. 13A-13B), using McMaster-7541A77 Devon epoxy. The epoxy was cured at room temperature for 24 h. The membrane was thoroughly cleaned by deionized (DI) water and immersed in 50 wt % aqueous solution of isopropyl alcohol (IPA) for 24 h. Untreated membrane was dried in a JeioTech ON-01E-120 oven at 75° C. for 30 min. For surface treatment, lauric aldehyde (LA) and sulfuric acid (H₂SO₄) were purchased from Sigma Aldrich (CAS No. 112-54-9 and CAS No. 7664-93-9, respectively). 20 mM aqueous solution of LA was prepared, and H₂SO₄ was added to adjust the pH value to 2. About 1 ml LA solution was added onto the PA membrane surface, filling the steel frame. The setup was heated at 75° C. for 30 min in a JeioTech ON-01E-120 oven. Then, the LA solution was removed and the membrane was repeatedly rinsed by DI water, immersed in DI water at 50° C. for 2 h, dried at 75° C. for 30 min, and rested at ambient temperature for 24 h. The Viton fluoroelastomer outer ring was placed onto the steel inner frame.

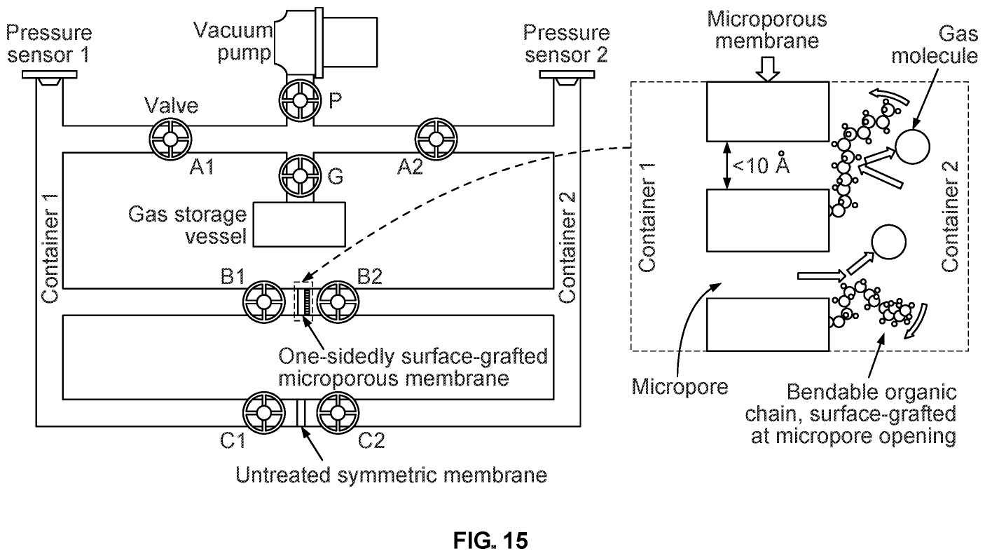

FIG. 14 is a schematic of an embodiment of an experimental setup. The containers mainly consisted of thin-walled stainless steel vacuum hoses, four-way connectors, and flexible couplings, and were connected to a MTI EQ-FYP-Pump-110 vacuum pump, two Inficon SKY-CDG200D pressure sensors, and a pentafluoroiodoethane (C₂F₅I) gas storage vessel (Sigma Aldrich, CAS No. 354-64-3). Vacuum clamps (see the inset at the upper-right corner of FIG. 14) and vacuum grease are used at all the connections. All the connections and valves were carefully adjusted, until satisfactory reference curves were obtained. The compound o-ring with one-sidedly surface-grafted membrane was placed in between valves B1 and B2. An untreated membrane was mounted on a similar compound o-ring and placed in between valves C1 and C2. FIG. 15 depicts the assembled system. FIGS. 13B, 14, and 15 are not to scale. In some tests, the untreated membrane between valves C1 and C2 is replaced by a non-permeable solid polycarbonate film. The inset on the right-hand side of FIG. 15 provides a magnified view of dodecyl chains covering micropores. The organic chain tends to be pushed close by gas molecules moving toward the micropore from right to left, while can be pushed open in the inverse direction.

Valve G was closed, and all the other valves were open. The vacuum pump was turned on. The gas pressure was reduced to below 0.06 mTorr and kept for ˜1 h. The pressure sensors were calibrated. Valve P was closed, and the pump was turned off. Valve G was opened, and C₂F₅I gas slowly flew into the containers, until the pressure sensor readings reached ˜0.8 Torr. Valve G was closed, and the system rested for 2 h. If a membrane is to be changed, the valves across it would be closed and the gas pressure was maintained in the rest of the system. After the membrane change, the operation of vacuum pump was repeated. The measured properties include the gas pressures in container 1 and container 2, by pressure sensor 1 and pressure sensor 2, respectively. When the initial gas pressure was about 1.2 Torr, the measured steady-state gas pressure difference was 1.1˜1.4 mTorr. Thus, a nonchaotic region may be investigated via measurements of properties of regular regions.

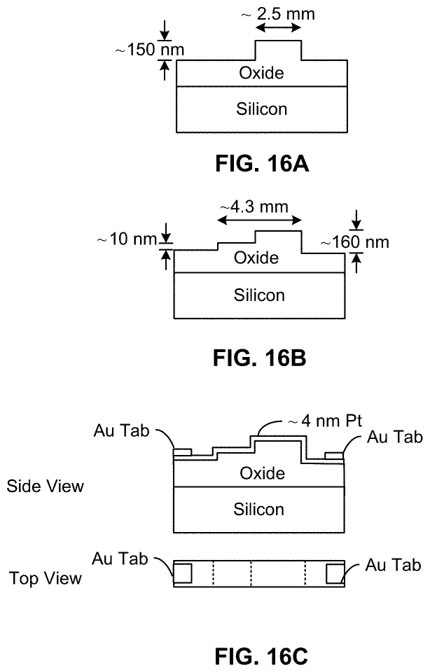

FIGS. 16A-16C depict an embodiment of an apparatus usable in investigating the behavior of charge carriers in nonchaotic systems during formation. FIGS. 16A-16C are not to scale. In particular, FIGS. 16A-16C indicates a technique for forming a system analogous to system 800. Although described in the context of specific materials, processes, and/or components, other materials, processes, and/or components may be used in other embodiments. A thermally oxidized (100) silicon wafer (“Silicon”) was obtained from Waferpro (SKU: X040073000W). The wafer thickness was 525±25 μm and the oxide layer thickness was 300 nm±5%. The as-received wafer was diced into 1×1 cm chips by a Disco-3220 Automatic Dicing Saw. The asymmetric structure was processed through a two-stepped procedure. The first step was to fabricate a 150-nm-deep nanostep couple (FIG. 16A). The distance between the two nanosteps was ˜2.5 mm; the width was ˜2 mm. The silicon chip was sequentially ultrasonicated in acetone, methanol, and isopropyl alcohol (IPA) in a clean glass beaker (5 min for each liquid), and immersed in de-ionized (DI) water for 30 sec, followed by drying with a nitrogen gun. In a Laurel spin coater, Negative Resist NR9-1500 was dispersed on the chip, with the spinning speed of 3500 rpm for 40 sec. The chip was prebaked at 150° C. for 1 min. The photoresist was exposed to intense light through a pattern mask in a MLA 150 machine. The wavelength of the light was 375 nm, with the dose of 1450 mJ/cm². Post-exposure bake (PEB) was performed at 115° C. for 1 min. The coated chip was developed in Resist Developer RD6 for 16 sec, rinsed in DI water for 30 sec, and dried with a nitrogen gun. Plasmalab 100 was employed to etch the oxide layer, by using an Oxford Plasmalab 100 RIE/ICP system. The processing temperature was 30° C.; the pressure was 30 mT; the He pressure was 8 Torr; the RIE power was 200 W; the flow rate of CHF₃ and Ar were both 75 sccm; the processing time was 300 sec (for the 150-nm nanostep) or 20 sec (for the 10-nm nanostep) (FIG. 16B). The photoresist layer was removed through ultrasonication in acetone for 30 min, after which the chip was immersed in DI water for 30 sec and dried with a nitrogen gun. PlasmaEtch 100 was utilized to remove the residuals. The RIE power was 250 W. The flow rate of O₂ was 5 sccm, and the etching time was 1 min. To fully remove the organic and inorganic contaminates, RCA cleaning was carried out. The chip was ultrasonically cleaned in Solution-1 (H₂O:H₂O₂:NH₄OH=10:2:1) for 10 min at 70±5° C., and dipped in DI water for 1 min, in buffered oxide etch (BOE) for 10 sec, and in DI water for another 1 min. The sample was then ultrasonically cleaned in Solution-2 (H₂O:H₂O₂:HCl=8:2:1) for 10 min at 70±5° C., followed by dipping in DI water for 1 min, in BOE for 10 sec, and in DI water for another 1 min. The RCA cleaning procedure was repeated twice. A similar etching process was carried out to produce a new 10-nm-deep nanostep on one side, and deepen the nanostep by 10 nm on the other side. The distance between the two etching locations was ˜2.5 mm; the width was nearly the same as in the first step (˜2 mm). Crosshairs were placed at the corners of the pattern masks for alignment. The 10-nm nanostep would be used as the nonchaotic region. The other side (the 160-nm “bump”) was relatively large-sized, equivalent to a wide ramp (similar to FIG. 7). A thin platinum (Pt) layer was deposited on the chip through atomic layer deposition (ALD), with the layer thickness being ˜4 nm. Then, similar to the above procedure, a photoresist layer is coated on top of Pt, and created a number of strip patterns across the nanosteps. The strip width was ˜200 μm. The axial direction was perpendicular to the edge of the nanostep. To remove the unmasked portion of Pt, reactive ion etching (RIE) with a Trion etcher machine is used. The processing pressure was 12 mT; the flow rate of Cl₂ was 8 sccm; the flow rate of Ar was 32 sccm; the RIE RF power was 133 W; the ICP RF power was 200 W; the etching temperature was 18° C.; the processing time was 300 sec. After etching, to remove the photoresist, ultrasonication was performed in acetone for 30 min, followed by RCA cleaning. Finally, 1.25×1.25 mm gold (Au) tabs were deposited on both ends of the Pt strips, using a Temescal BJD 1800 Ebeam Evaporator (FIG. 16C). The vacuum pressure was lower than 10⁻⁶ Torr; the deposition rate was 0.4 nm/sec; the total thickness was ˜80 nm. The chip was rinsed in a glass beaker with acetone for 5 min, followed by RCA cleaning.

Two 15.2×15.2×0.6 cm stainless-steel plates (analogous to electret plates 870 and 880 of FIG. 8) were employed to generate a uniform electric field. They were placed in parallel and connected to a Glassman FJ Series-120 Watt High-Voltage Power Supply unit. The chip was contained in a plastic case (9-Slot 2×2 Bare Die CSP Tray) on the bottom steel plate. The Au tabs at the two ends of a Pt strip were connected to a B2987a Femto/Pico-ammeter (FPA), with the measurement resolution below 1 fA. Economy Joystick Positioners, holders, and tips were using for pad probing (Signatone). The measurement data were collected by the Quick IV Measurement software. The voltage and the gap between the two steel plates were 5 kV and 2.5 cm, respectively. The electric field strength (E) was ˜0.2 MV/m; its direction was toward the top surface of the chip. Compared to the background signals without E, three samples demonstrated significantly larger currents after the electric field was turned on. When the initial FPA readings (without E) were 0.2 pA, −0.03 pA, or 1 pA, the steady-state FPA readings (with E) were 4 pA, 2 pA, and 90 pA, respectively. A similar setup may also be utilized to study the temperature changes associated with E at the two sides of the nanolayer.

Thus, systems that include regular and nonchaotic regions may be formed and used in investigating the behavior of particles in nonchaotic regions. More specifically, the behavior of particles in nonchaotic regions may be examined and utilized by measuring characteristics of the regular regions. Thus, the study of particles in nonchaotic regions may be facilitated.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system, comprising:
a first region configured to retain particles and having a first characteristic dimension; and
a second region communicatively coupled with the first region such that the particles can travel between the first region and the second region, the second region having a second characteristic dimension of not larger than twice a characteristic length for the particles;
wherein the second region includes a barrier to the travel of the particles from or to the first region.

2. The system of claim 1, wherein the characteristic length is selected from a particle mean free path and a particle size.

3. The system of claim 1, wherein the first region and the second region are communicatively coupled such that at least one of mass or energy is transferable between the first region and the second region.

4. The system of claim 1, wherein the barrier is selected from an energy barrier and an asymmetric physical barrier.

5. The system of claim 4, wherein the asymmetric physical barrier includes an asymmetric movable part coupled with an aperture between the first region and the second region.

6. The system of claim 4, wherein the energy barrier includes at least one of an electric field for the particles including charged particles or a gravitational field.

7. The system of claim 1, further comprising:
a third region communicatively coupled with at least the second region.

8. The system of claim 7, wherein the third region is communicatively coupled with the first region such that the particles can travel at least one of between the first region and the second region, between the second region and the third region, or between the third region and the first region.

9. The system of claim 7, wherein the third region is communicatively coupled with the first region through the second region.

10. A system, comprising:
a first region configured to such that particles therein are in a regular state; and
a second region communicatively coupled with the first region and configured such that the particles in the second region are in a nonchaotic state.

11. The system of claim 10 wherein the first region has a first characteristic dimension and the second region has a second characteristic dimension less than the first characteristic dimension.

12. The system of claim 11, wherein the second characteristic dimension is not larger than twice a particle characteristic length.

13. The system of claim 10, wherein the first region and the second region are communicatively coupled such that at least one of mass or energy is transferable between the first region and the second region.

14. The system of claim 10, wherein the second region includes a barrier to the travel of the particles from the first region.

15. The system of claim 14, wherein the barrier is selected from an energy barrier and an asymmetric physical barrier.

16. The system of claim 10, further comprising:
a third region communicatively coupled with at least the second region, the third region being configured such that at least a portion of the particles in the third region is in the regular state.

17. The system of claim 16, wherein the third region is communicatively coupled with the first and the second regions such that the particles can travel at least one of between the first region and the second region, between the second region and the third region, or between the third region and the first region.

18. A method, comprising:
providing an apparatus including a first region and a second region, the first region being configured to retain particles and having a first characteristic dimension, the second region being communicatively coupled with the first region such that the particles can travel between the first region and the second region and having a second characteristic dimension of not larger than twice a characteristic length for the particles; and
providing the particles in the apparatus.

19. The method of claim 18, further comprising:
studying particle behavior in at least one of the first region or the second region.

20. The method of claim 18, wherein the providing the apparatus further includes:
providing a third region communicatively coupled with the first region and the second region such that the particles can travel at least one of between the first region and the second region, between the second region and the third region, or between the third region and the first region.
